(19) United States
(12) Patent Application Publication
(10) Pub. No.: US 2022/0238599 A1
(43) Pub. Date: Jul. 28, 2022

(54) DISPLAY DEVICE AND METHOD FOR MANUFACTURING DISPLAY DEVICE

(71) Applicant: Japan Display Inc., Tokyo (JP)

(72) Inventor: Kazuyuki YAMADA, Tokyo (JP)

(21) Appl. No.: 17/723,619

(22) Filed: Apr. 19, 2022

Related U.S. Application Data
(63) Continuation of application No. PCT/JP2020/038718, filed on Oct. 14, 2020.

(30) Foreign Application Priority Data
Oct. 21, 2019 (JP) 2019-191694

(51) Int. Cl. H01L 27/15; H01L 33/56; H01L 33/00

(52) U.S. Cl. CPC H01L 27/156; H01L 2933/005; H01L 33/005; H01L 33/56

(57) ABSTRACT

According to one embodiment, a display device includes an array substrate having a first main surface on which a plurality of light emitting elements spaced apart from each other is provided and a second main surface located on an opposite side of the first main surface, an optical resin layer provided between the plurality of light emitting elements and on the plurality of light emitting elements on the first main surface of the array substrate, and a light transmitting layer provided on the optical resin layer. The optical resin layer has a refractive index of 1.40 or more and 1.60 or less, and translucency of 90% or more.

### CROSS-REFERENCE TO RELATED APPLICATIONS

This application is a Continuation Application of PCT Application No. PCT/JP2020/038718, filed Oct. 14, 2020 and based upon and claiming the benefit of priority from Japanese Patent Application No. 2019-191694, filed Oct. 21, 2019, the entire contents of all of which are incorporated herein by reference.

### FIELD

Embodiments described herein relate generally to a display device and a method for manufacturing the display device.

### BACKGROUND

As a display device, an LED display device using a light-emitting diode (LED) which is a spontaneous light-emitting element is known. In recent years, as a higher-definition display device, a display device in which minute light-emitting diodes called micro LEDs are mounted on an array substrate (hereinafter, referred to as a micro LED display device) has been developed.

Unlike a conventional liquid crystal display and an organic EL display, this micro LED display is formed by mounting a large number of chip-shaped micro LEDs (hereinafter, notated as an LED chip) in a display region, and thus it is easy to achieve high definition together with a large size, and the micro LED display is attracting attention as a next-generation display.

### BRIEF DESCRIPTION OF THE DRAWINGS

FIG. 1 is a schematic plan view of a display device according to a first embodiment.

FIG. 2 is a schematic cross-sectional view taken along line ii-ii of FIG. 1 according to the first embodiment.

FIG. 3 is a schematic cross-sectional view of a display device according to a second embodiment.

FIG. 4 is a schematic cross-sectional view of a display device according to a third embodiment.

FIG. 5 is a flowchart for describing a method for manufacturing a display device according to an embodiment.

FIG. 6 is a schematic cross-sectional view of an array substrate used in the method for manufacturing the display device according to the embodiment.

FIG. 7 is a schematic cross-sectional view for describing the method for manufacturing the display device according to the embodiment.

FIG. 8 is another schematic cross-sectional view for describing the method for manufacturing the display device according to the embodiment.

### DETAILED DESCRIPTION

The present embodiment provides a high-reliability display device capable of suppressing or preventing damage to a micro LED due to external force such as impact, dropping, or curving.

Hereinafter, some embodiments will be described with reference to the drawings. The same configurations or similar configurations are denoted by the same reference signs throughout the embodiments, and redundant description will be omitted. In addition, each drawing is a schematic diagram for promoting understanding of the embodiments, and the shape, size, ratio, and the like thereof may be different from the actual shape, size, ratio, and the like. However, each drawing is merely an example, and does not limit the interpretation of the present invention.

In the following embodiments, a micro LED display device (micro LED display) using a micro LED which is a spontaneous light-emitting element will be described as an example of the display device, but the present invention can also be applied to other display devices, for example, a backlight used for a liquid crystal display device. In addition, in the following embodiments, a passively driven micro LED display device will be described, but the present invention can also be applied to an active matrix driving micro LED display device. In addition, for example, in the present specification, an LED having a thickness of 1 μm or more and 300 μm or less is defined as a micro LED.

### First Embodiment

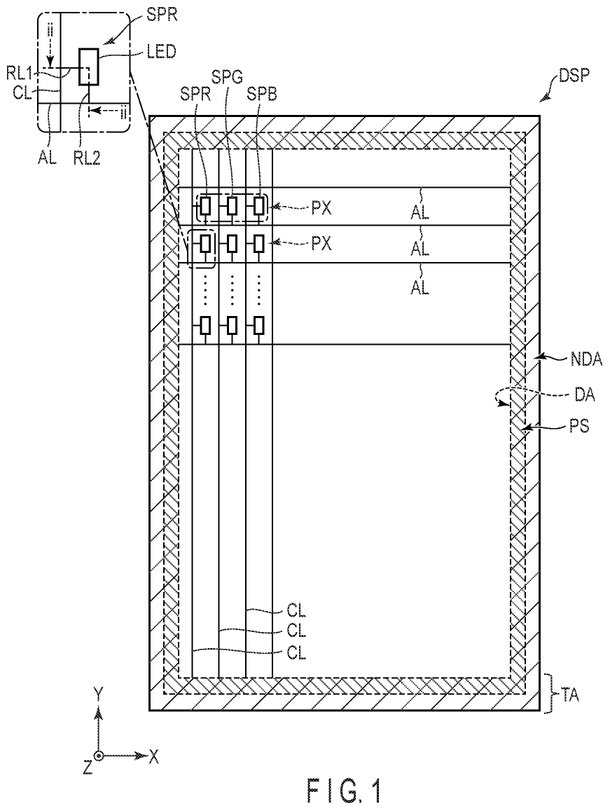

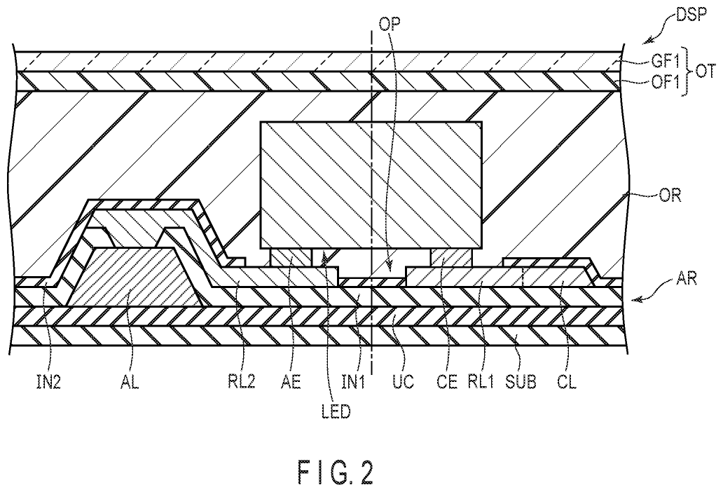

A display device DSP according to a first embodiment will be described in detail with reference to FIGS. 1 and 2. FIG. 1 is a schematic plan view of the display device according to the first embodiment, and FIG. 2 is a schematic cross-sectional view taken along line ii-ii of FIG. 1 according to the first embodiment.

In the embodiment, a direction parallel to a short side of the display device DSP is a first direction X, a direction parallel to a long side of the display device DSP is a second direction Y, and a direction perpendicular to the first direction X and the second direction Y is a third direction Z. Incidentally, the first direction X and the second direction Y are orthogonal to each other, but may intersect at an angle other than 90°.

In addition, in the embodiment, the positive direction in the third direction Z is defined as on or above, and the negative direction in the third direction Z is defined as immediately under or below. In the case of “the second member above the first member” and “the second member below the first member”, the second member may be in contact with the first member or may be located away from the first member. In the latter case, the third member may be interposed between the first member and the second member. In contrast, in the case of “the second member on the first member” and “the second member immediately under the first member”, the second member is in contact with the first member. Moreover, viewing the display device DSP from the positive direction in the third direction Z is defined as a planar view.

As shown in FIG. 1, the display device DSP has a display region DA and a non-display region NDA surrounding the display region DA and formed in a frame shape.

The display region DA is a region for displaying an image and has, for example, a rectangular shape. In the display region DA, a plurality of pixels PX, a plurality of scanning lines (anode lines) AL, and a plurality of data signal lines (cathode lines) CL orthogonal to the plurality of scanning lines AL are disposed.

The plurality of pixels PX is, for example, an m×n (provided that m and n are positive integers) number of pixels, and is arrayed in a matrix. Each of the pixels PX includes a plurality of sub-pixels. In other words, each of the pixels PX includes three types of sub-pixels, a sub-pixel SPR exhibiting a first color, a sub-pixel SPG exhibiting a second color, and a sub-pixel SPB exhibiting a third color. The sub-pixel SPR includes a light emitting element LED that emits the first color, the sub-pixel SPG includes a light emitting element LED that emits the second color, and the sub-pixel SPB includes a light emitting element LED that emits the third color. Here, the first color, the second color, and the third color are, for example, red, green, and blue, respectively.

As shown in FIG. 1, the light emitting element LED that emits the first color is connected to a first relay line RL1 extending from a data signal line CL and a second relay line RL2 in contact with a scanning line AL, and is electrically connected to the data signal line CL and the scanning line AL. Similarly, each of the light emitting element LED that emits the second color and the light emitting element LED that emits the third color is also connected to the first relay line RL1 and the second relay line RL2, and is electrically connected to a data signal line CL and a scanning line AL.

The non-display region NDA is indicated by hatching in FIG. 1, and has, for example, a terminal area TA located adjacent to the display region DA. The terminal area TA includes a terminal (not shown in the drawings) for electrically connecting the display device DSP to an external device (for example, a flexible printed circuit, a printed wiring substrate, a driver IC chip, or the like) or the like.

A resin wall PS described later is provided in the non-display region NDA. The resin wall PS is formed in the non-display region NDA so as to surround the display region DA. The resin wall PS is indicated by crosshatching in FIG. 1. However, the resin wall PS is not limited to a structure surrounding all four sides of the display region DA as shown in FIG. 1. The resin wall PS may be formed on only one side of the terminal area TA, only two left and right sides of the terminal area TA, only one opposite side of the terminal area TA, or any three of the four sides. In some embodiments, the resin wall PS may not be formed in the non-display region NDA.

In addition, the strength of the non-display region NDA of the display device DSP can be improved by providing the resin wall PS in the non-display region NDA.

As shown in FIG. 2, the display device DSP further includes an array substrate AR, an optical resin layer OR, and a light transmitting layer OT. The array substrate AR includes a substrate SUB.

The substrate SUB is, for example, a glass substrate of quartz, alkali-free glass, or the like, or a resin substrate of polyimide, polyamidimide, polyaramide, or the like. The substrate SUB is not limited to those described above as long as the substrate SUB can withstand the processing temperature in the manufacturing of the array substrate AR described later. When the resin substrate described above or the bendable slim glass substrate described above is used as the substrate SUB, the array substrate AR has plasticity, so that the display device DSP can be configured as a sheet display.

An undercoat layer UC is disposed on the substrate SUB. The undercoat layer UC is formed of, for example, an inorganic material such as silicon oxide (SiO₂) in order to improve adherence to the substrate SUB. In addition, the undercoat layer UC may be formed of an inorganic material such as silicon nitride (SiN), for example, as a block film for blocking moisture and impurities from the outside. The undercoat layer UC may have a single-layer structure of the inorganic material described above, or may have a multilayer structure (two-layer structure, three-layer structure, or the like) of a plurality of inorganic materials.

The scanning lines AL are formed on the undercoat layer UC. Each of the scanning lines AL has a multilayer structure of a plurality of metal materials having a light blocking property, and may have, for example, a three-layer structure of titanium (Ti) as an upper layer, aluminum (Al) as a middle layer, and titanium (Ti) as a lower layer, or a three-layer structure of molybdenum (Mo) as an upper layer, aluminum (Al) as a middle layer, and molybdenum (Mo) as a lower layer.

An interlayer insulating film IN1 is formed on the undercoat layer UC and the scanning lines AL. The interlayer insulating film IN1 exposes a part of surfaces of the scanning lines AL. The interlayer insulating film IN1 is, for example, an inorganic insulating film such as silicon oxide.

The data signal lines CL, the first relay line RL1, and the second relay line RL2 are formed on the interlayer insulating film IN1. The data signal lines CL are electrically insulated by the interlayer insulating film IN1 at intersections with the scanning lines AL as shown in FIG. 1. The first relay line RL1 is a branch portion elongated from the data signal lines CL, that is, a part of the data signal lines CL, and is formed integrally with the data signal lines CL. The second relay line RL2 is in contact with the surfaces of the scanning lines AL exposed from the interlayer insulating film IN1.

The data signal lines CL, the first relay line RL1, and the second relay line RL2 are each formed of a metal material having a common light blocking property. The data signal lines CL, the first relay line RL1, and the second relay line RL2 have a multilayer structure of a metal material having a light blocking property, and have, for example, a three-layer structure of titanium (Ti) as an upper layer, aluminum (Al) as a middle layer, and titanium (Ti) as a lower layer. However, the multilayer structure of the metal material having the light blocking property is not limited to the three-layer structure.

A protective insulating film IN2 is formed on the interlayer insulating film IN1, the data signal lines CL, the first relay line RL1, and the second relay line RL2. The protective insulating film IN2 is, for example, an inorganic insulating film such as silicon oxide. In the protective insulating film IN2, opening portions OP are formed at positions where the light emitting elements LED are mounted. The opening portions OP expose a part of each surface of the first relay line RL1 and the second relay line RL2.

A first electrode (cathode electrode) CE is formed on the first relay line RL1, and a second electrode (anode electrode) AE is formed on the second relay line RL2. More specifically, the first electrode CE is connected to the surface of the first relay line RL1 exposed from the opening portions OP of the protective insulating film IN2, and the second electrode AE is connected to the second relay line RL2 exposed from the opening portions OP of the protective insulating film IN2.

A method for joining between the first electrode CE and the first relay line RL1 and a method for joining between the second electrode AE and the second relay line RL2 are not particularly limited as long as good conduction can be secured between the first electrode CE and the first relay line RL1 and between the second electrode AE and the second relay line RL2 and the other constituent parts of the array substrate AR are not damaged. The joining methods include, for example, a reflow process using a low-temperature melting solder material, a method for disposing the light emitting elements LED in the opening portions OP through a conductive paste and then sintering the light emitting elements LED, and a method for solid layer joining such as ultrasonic welding using similar materials for the surfaces of the first relay line RL1 and the second relay line RL2 and the first electrode CE and the second electrode AE of each of the light emitting elements LED.

The first electrode CE and the second electrode AE are included in each of the light emitting elements LED. Each of the light emitting elements LED further includes an emitting layer (not shown in the drawings) between the first electrode CE and the second electrode AE. The emitting layer is formed of, for example, a two-element, three-element, or four-element compound selected from the group of phosphorus, arsenic, nitrogen, silicon, gallium, aluminum, indium, and germanium.

The array substrate AR has a first main surface and a second main surface located on the opposite side of the first main surface. In the example shown in FIG. 2, the first main surface of the array substrate AR corresponds to a surface on which the light emitting elements LED are mounted, and the second main surface of the array substrate AR corresponds to a surface on the substrate SUB side. Each of the light emitting elements LED is mounted on the first relay line RL1 and the second relay line RL2 of the array substrate AR. In other words, the array substrate AR has the first main surface on which the plurality of light emitting elements LED spaced apart from each other is provided, and the second main surface located on the opposite side of the first main surface.

Although the array substrate AR has been described as above, the structure of the array substrate AR is not limited thereto, and the array substrate AR may have a drive transistor (not shown in the drawings) for each sub-pixel (SPR, SPG, SPB) in order to perform control as an active matrix.

The optical resin layer OR is provided between the plurality of light emitting elements LED and on the plurality of light emitting elements LED on the first main surface of the array substrate AR. The optical resin layer OR has, for example, a refractive index of 1.40 or more and 1.60 or less and translucency of 90% or more. When the refractive index of the optical resin layer OR is less than 1.40 or more than 1.60, light radiated from the light emitting elements LED is reflected in the optical resin layer OR, so that it is hardly emitted to the outside, and the luminance of the display device DSP may be degraded. In addition, when the translucency of the optical resin layer OR is less than 90%, the intensity of light radiated from the light emitting elements LED may be reduced by the optical resin layer OR, and the luminance of the display device DSP may be degraded. In some embodiments, the optical resin layer OR preferably has, for example, a refractive index of 1.50 or more and 1.60 or less and translucency of 95% or more.

The optical resin layer OR has a thickness that covers the plurality of light emitting elements LED. The thickness of the optical resin layer OR is, for example, in a range of 10 μm to 200 μm. Here, the thickness of the optical resin layer OR refers to the shortest distance from the surface of the protective insulating film IN2 on the first relay line RL1 and the data signal lines CL of the array substrate AR to the outermost surface (contact surface between the optical resin layer OR and the light transmitting layer OT) of the optical resin layer OR in the example shown in FIG. 2.

The optical resin layer OR is formed using, for example, an optical resin material such as an ultraviolet curing resin or a thermosetting resin. The ultraviolet curing resin is, for example, an acrylic resin, a silicone-based resin, a styrene-based resin, a polycarbonate-based resin, a polyolefin-based resin, or the like. The thermosetting resin is, for example, an epoxy-based resin, a phenol-based resin, an unsaturated polyester-based resin, a urea-based resin, a melamine-based resin, a diallyl phthalate-based resin, a vinyl ester-based resin, polyimide, polyurethane, or the like.

In some embodiments, the optical resin layer OR has an anticorrosion property for the plurality of light emitting elements LED. The optical resin layer OR having an anticorrosion property is, for example, a resin that does not corrode or hardly corrodes each metal material of the first electrode CE, the emitting layer, and the second electrode AE of each of the plurality of light emitting elements LED, and the first relay line RL1 and the second relay line RL2. Such a resin is an acid-free resin. By providing the optical resin layer OR having an anticorrosion property, it is possible to suppress or prevent the occurrence of a display failure of the display device DSP due to the corrosion of the light emitting elements LED, the first relay line RL1, and the second relay line RL2.

In some embodiments, the optical resin layer OR may have light resistance. The optical resin layer OR having light resistance is, for example, a resin which is not decomposed or hardly decomposed by ultraviolet rays to be colored in yellow and has strength that is not degraded or hardly degraded by ultraviolet rays. Such a resin is an acrylic resin or a polycarbonate resin. By providing the optical resin layer OR having light resistance, it is possible to prevent degradation in the strength of the display device DSP due to light such as ultraviolet rays or to prevent a change in the hues of the colors of light emitted from the light emitting elements LED due to the optical resin layer OR.

The light transmitting layer OT is provided on the optical resin layer OR. The light transmitting layer OT can transmit light that has been radiated from the light emitting elements LED and passed through the optical resin layer OR, and can function as a film for protecting the light emitting elements LED from an external force or the like applied to the light emitting elements LED.

In some embodiments, the light transmitting layer OT is a first glass film GF1, a first optical film OF1, or a stacked layer body thereof.

The first glass film GF1 is formed of, for example, a cover member such as a cover glass or a touch panel substrate or the like. The first glass film GF1 has a thickness of, for example, 10 μm to 100 μm. The first glass film GF1 can have both translucency of, for example, 90% or more and light resistance, or can have either translucency of, for example, 90% or more or light resistance. The first glass film GF1 is, for example, a thin glass film. When the array substrate AR is a flexible substrate requiring flexibility, the first glass film GF1 can also be curved in accordance with the curve of the array substrate AR.

The first optical film OF1 has a thickness of, for example, 10 μm to 100 μm. The first optical film OF1 can have both translucency of, for example, 90% or more and light resistance, or can have either translucency of, for example, 90% or more or light resistance. The first optical film OF1 is, for example, an optical transparent resin (OCR: Optical Clear Resin or LOCA: Liquid Optically Clear Adhesive) such as a liquid crystal ultraviolet curing resin, an optical clear adhesive (OCA) film, or the like. The first optical film OF1 has adhesiveness to the first glass film. Furthermore, when the first optical film OF1 is an optically transparent resin, the first optical film OF1 may have a function of making uniform the height of the optical resin layer OR covering the light emitting elements LED by increasing the film thickness thereof.

The configuration and stacking order of the stacked layer body including the first glass film GF1 and the first optical film OF1 are not particularly limited, and the first glass film GF1 may be disposed on the optical resin layer OR side, the first optical film OF1 may be disposed on the optical resin layer OR side, and the stacked layer body may include two or more first glass films GF1 or two or more first optical films OF1.

In the display device DSP of the first embodiment, the optical resin layer OR having a refractive index of 1.40 or more and 1.60 or less and translucency of 90% or more is provided between the plurality of light emitting elements LED and on the plurality of light emitting elements LED on the first main surface of the array substrate AR. As a result, it is possible to obtain a high-reliability display device DSP in which the optical resin layer OR can suppress or prevent damage to the plurality of light emitting elements LED due to external force such as impact, dropping, or curving.

In addition, since the optical resin layer OR has a refractive index of 1.40 or more and 1.60 or less and translucency of 90% or more, light radiated from the light emitting elements LED is emitted to the outside without being degraded in the optical resin layer OR. Therefore, the display device DSP having high luminance can be obtained.

### Second Embodiment

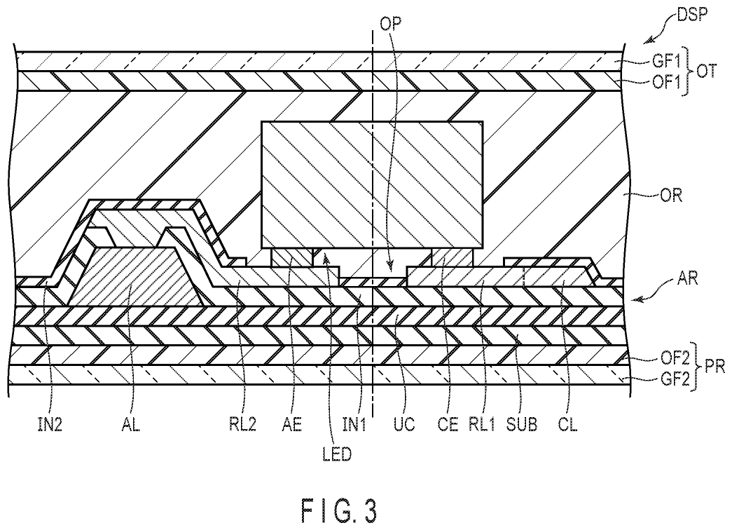

A display device DSP according to a second embodiment will be described in detail with reference to FIG. 3. FIG. 3 is a schematic cross-sectional view of the display device according to the second embodiment. The display device DSP according to the second embodiment is different from the display device DSP according to the first embodiment in that a protective layer PR is provided on a second main surface of an array substrate AR.

The protective layer PR is a second glass film GF2, a second optical film OF2, or a stacked layer body thereof. Since the second glass film GF2, the second optical film OF2, and the stacked layer body thereof have the same configurations as those of the first glass film GF1, the first optical film OF1, and the stacked layer body thereof, the description thereof will be omitted.

In the display device DSP of the second embodiment, the protective layer PR is provided on the second main surface of the array substrate AR. As a result, the protective layer PR improves the strength of the display device DSP, and a higher-reliability display device DSP can be obtained.

### Third Embodiment

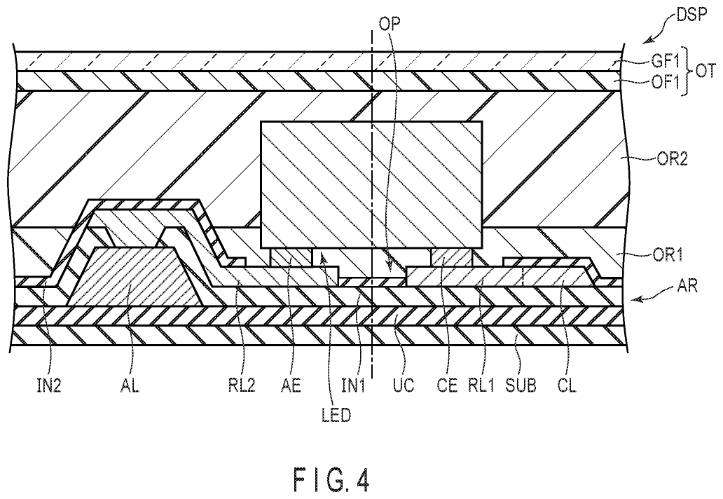

A display device DSP according to a third embodiment will be described in detail with reference to FIG. 4. FIG. 4 is a schematic cross-sectional view of the display device according to the third embodiment. The display device DSP according to the third embodiment is different from the display device DSP according to the first embodiment in that the optical resin layer OR includes a first optical resin layer OR1 located on the first main surface side of the array substrate AR and a second optical resin layer OR2 located on the light transmitting layer OT side.

The first optical resin layer OR1 is provided on a part of the first relay line RL1, the second relay line RL2, and the protective insulating film IN2 of the array substrate AR, and is provided so as to be filled in a space (for example, a space extending between a first electrode CE and a second electrode AE, or the like) immediately under light emitting elements LED.

The second optical resin layer OR2 is provided on the first optical resin layer OR1 and the protective insulating film IN2 exposed from the first optical resin layer OR1. In addition, the second optical resin layer OR2 is provided between the plurality of light emitting elements LED and on the plurality of light emitting elements LED on the first main surface of the array substrate AR.

The first optical resin layer OR1 can suppress or prevent degradation in adhesive force of the optical resin layer OR and/or generation of air bubbles in the optical resin layer OR, which can be caused by difficulty in filling the space with the optical resin material when the space immediately under the light emitting elements LED is small in step S2 of a method for manufacturing a display device described later.

For this reason, the first optical resin layer OR1 strongly adheres to the first electrode CE, the second electrode AE, the first relay line RL1, and the second relay line RL2, and can suppress or prevent peeling of the light emitting elements LED at the time of applying the second optical resin layer OR2 in step S3 of the method for manufacturing a display device, and/or peeling of the light emitting elements LED due to an external force such as an impact on the display device DSP.

In addition, the first optical resin layer OR1 can suppress or prevent degradation in display quality resulting from air bubbles generated in the optical resin layer OR.

For example, the first optical resin layer OR1 is preferably thinner than the second optical resin layer OR2 and thicker than at least the first electrode CE and the second electrode AE.

The first optical resin layer OR1 may be made of the same material as that of the second optical resin layer OR2 or may be made of a different material from that of the second optical resin layer OR2 as long as the first optical resin layer OR1 is thinner than the second optical resin layer OR2. In a case where the first optical resin layer OR1 is formed of a material different from that of the second optical resin layer OR2, the optical resin material forming the first optical resin layer OR1 has a viscosity smaller than that of the optical resin material forming the second optical resin layer OR2, so that the optical resin material forming the first optical resin layer OR1 easily flows between the first electrode CE and the second electrode AE and into the space immediately under the light emitting elements LED.

Furthermore, since the first optical resin layer OR1 is formed of a material having a refractive index different from that of the second optical resin layer OR2, light emitted from the light emitting elements LED to the substrate SUB side is reflected toward the light transmitting layer OT side, and the emitted light intensity can be improved.

Since the first optical resin layer OR1 and the second optical resin layer OR2 are the same as the optical resin layer OR except for the above-described configuration, the description of materials, physical properties, and the like is omitted.

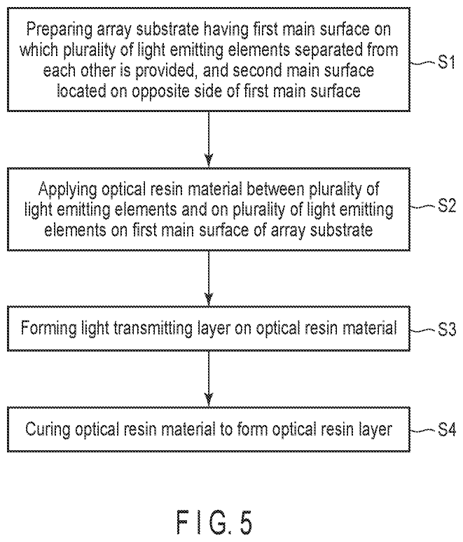

The method for manufacturing a display device according to an embodiment will be described with reference to FIG. 5. FIG. 5 is a flowchart for describing the method for manufacturing a display device according to the embodiment.

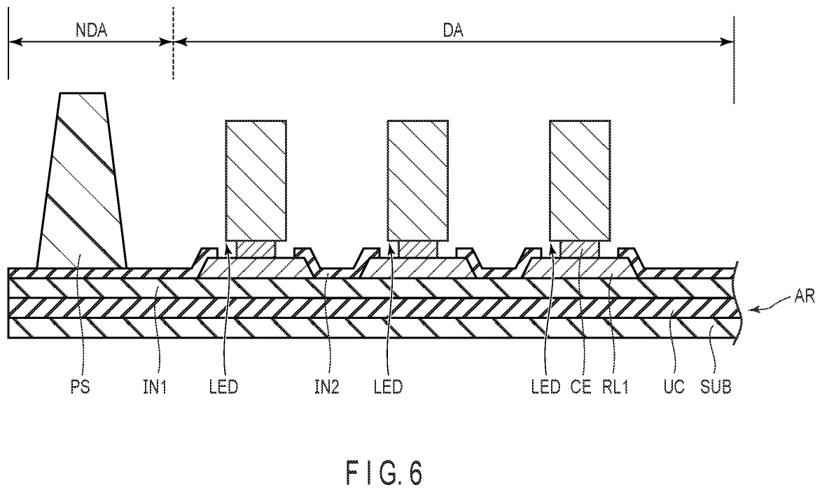

First, an array substrate AR that has a first main surface on which a plurality of light emitting elements LED spaced apart from each other is provided, and a second main surface located on the opposite side of the first main surface is prepared (step S1). Specifically, such an array substrate AR as shown in FIG. 6 is prepared. A resin wall PS is formed in a non-display region NDA of the array substrate AR shown in FIG. 6 so as to surround a display region DA.

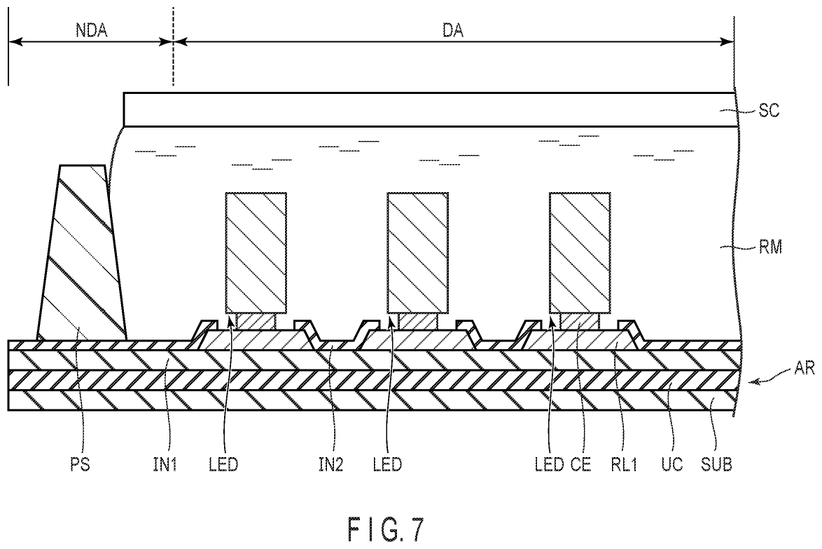

Next, an optical resin material is applied between the plurality of light emitting elements and onto the plurality of light emitting elements on the first main surface of the array substrate (step S2). Specifically, as shown in FIG. 7, the optical resin material RM is applied between the plurality of light emitting elements LED and onto the plurality of light emitting elements LED using a slit coater SC.

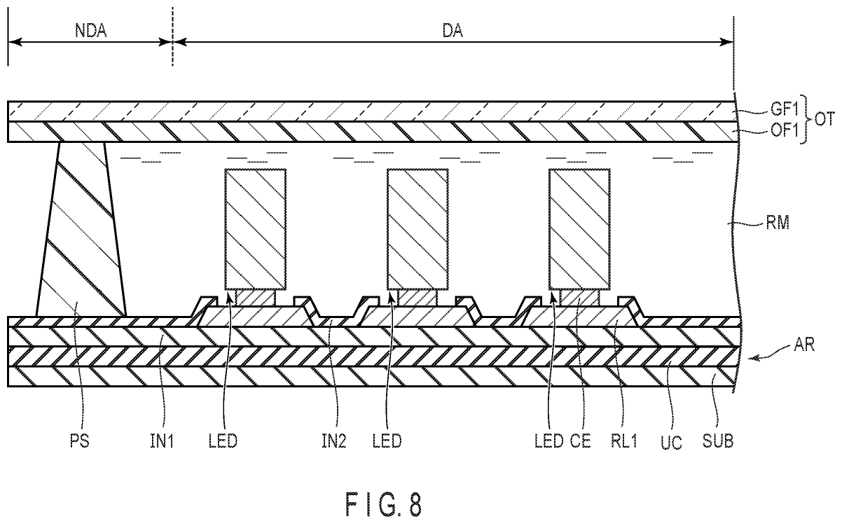

Next, a light transmitting layer is formed on the optical resin material (step S3). Specifically, as shown in FIG. 8, the above-described light transmitting layer OT is disposed on the optical resin material RM. In some embodiments, step S3 can be performed under a vacuum condition so that no air bubbles enter between the light transmitting layer OT and the optical resin material RM.

Next, an optical resin layer is formed by curing the optical resin material (step S4). Specifically, the optical resin material RM shown in FIG. 8 is cured to form the optical resin layer OR. For example, when the optical resin material RM is an ultraviolet curing resin, the optical resin layer OR can be formed by irradiating the optical resin material RM with ultraviolet rays. In addition, when the optical resin material RM is a thermosetting resin, the optical resin layer OR can be formed by heating the optical resin material RM. In this way, the display device DSP according to the embodiment can be manufactured.

Incidentally, in the above-described method for manufacturing the display device, the optical resin material may be cured in step S2, and step S4 may be omitted. Furthermore, in step S1, an array substrate AR in which a resin wall PS is not provided in a non-display region NDA may be prepared.

In some embodiments, when the resin wall is not provided on the array substrate prepared in step S1, a frame-shaped resin wall may be formed to surround the plurality of light emitting elements provided on the first main surface of the array substrate before step S2.

By forming the frame-shaped resin wall on the array substrate or by preparing the array substrate on which the frame-shaped resin wall is formed, it is possible to suppress or prevent the optical resin material from leaking to the outside beyond the non-display region in step S2. The height of the frame-shaped resin wall is preferably larger than the height of each light emitting element.

In some embodiments, in step S2, the optical resin material is applied such that, for example, the height of the optical resin material is equivalent to or greater than the height of the frame-shaped resin wall. By applying the optical resin material at a height equivalent to the height of the frame-shaped resin wall or exceeding the height of the frame-shaped resin wall, air bubbles and the like can be prevented from entering between the light transmitting layer and the optical resin layer, and a flat optical resin layer can also be formed without causing a difference in height resulting from a plurality of light emitting elements.

In some embodiments, in step S2, for example, the application conditions are preferably set such that the optical resin layer shrinks to a film thickness equivalent to at least the resin wall or the light emitting elements, and the surface is planarized.

In each of some embodiments, the method for manufacturing the display device according to the embodiment further includes forming a protective layer on the second main surface of the array substrate after curing the optical resin material. Specifically, after step S4, the protective layer PR is formed on the second main surface of the array substrate AR. The protective layer PR is, for example, formed by being bonded to the substrate SUB via an adhesive. In this way, the display device DSP according to the second embodiment as shown in FIG. 3 can be manufactured.

In each of some embodiments, the method for manufacturing the display device according to the embodiment applies a first optical resin material and a second optical resin material in step S2. Specifically, after the first optical resin material is applied and cured, the second optical resin material is applied. The display device DSP according to the third embodiment as shown in FIG. 4 can be manufactured by applying the first optical resin material and the second optical resin material.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A display device comprising:
an array substrate having a first main surface on which a plurality of light emitting elements spaced apart from each other is provided and a second main surface located on an opposite side of the first main surface;
an optical resin layer provided between the plurality of light emitting elements and on the plurality of light emitting elements on the first main surface of the array substrate; and
a light transmitting layer provided on the optical resin layer,
wherein
the optical resin layer has a refractive index of 1.40 or more and 1.60 or less, and translucency of 90% or more.

2. The display device according to claim 1, wherein the optical resin layer has an anticorrosion property for the plurality of light emitting elements.

3. The display device according to claim 1, wherein the light transmitting layer is a first glass film, a first optical film, or a stacked layer body thereof.

4. The display device according to claim 1, wherein a protective layer is provided on the second main surface of the array substrate.

5. The display device according to claim 4, wherein the protective layer is a second glass film, a second optical film, or a stacked layer body thereof.

6. The display device according to claim 1, wherein the optical resin layer includes a first optical resin layer located on the first main surface side of the array substrate and a second optical resin layer located on the light transmitting layer side.

7. A method for manufacturing a display device comprising:
preparing an array substrate having a first main surface on which a plurality of light emitting elements spaced apart from each other is provided and a second main surface located on an opposite side of the first main surface;
applying an optical resin material between the plurality of light emitting elements and on the plurality of light emitting elements on the first main surface of the array substrate;
forming a light transmitting layer on the optical resin material; and
curing the optical resin material to form an optical resin layer,
wherein
the optical resin layer has a refractive index of 1.40 or more and 1.60 or less and translucency of 90% or more.

8. The method for manufacturing a display device according to claim 7, wherein the optical resin layer has an anticorrosion property for the plurality of light emitting elements.

9. The method for manufacturing a display device according to claim 7, wherein the light transmitting layer is a first glass film, a first optical film, or a stacked layer body thereof.

10. The method for manufacturing a display device according to claim 7, further comprising forming a protective layer on the second main surface of the array substrate after curing the optical resin material.

11. The method for manufacturing a display device according to claim 10, wherein the protective layer is a second glass film, a second optical film, or a stacked layer body thereof.

12. The method for manufacturing a display device according to claim 7, further comprising forming a frame-shaped resin wall such that the resin wall surrounds the plurality of light emitting elements on the first main surface of the array substrate before applying the optical resin material.

13. The method for manufacturing a display device according to claim 12, wherein in the applying the optical resin material to a region in which the plurality of light emitting elements surrounded by the frame-shaped resin wall is provided, the optical resin material is applied at a height equivalent to a height of the frame-shaped resin wall or exceeding the height of the frame-shaped resin wall.

14. The method for manufacturing a display device according to claim 7, wherein a first optical resin material and a second optical resin material are applied in the applying the optical resin material between the plurality of light emitting elements and on the plurality of light emitting elements on the first main surface of the array substrate.
